(19) United States
(12) Patent Application Publication
(10) Pub. No.: US 2016/0155940 A1
(43) Pub. Date: Jun. 2, 2016

(54) INORGANIC LIGHT EMITTING MEMORY AND METHOD FOR PRODUCING THE SAME

(71) Applicant: National Taiwan University, Taipei (TW)

(72) Inventors: Yang-Fang Chen, Taipei (TW); Ying-Chih Lai, Taipei City (TW); Yi-Rou Liou, Taipei (TW); Che-Wei Chang, Taipei (TW)

(21) Appl. No.: 14/679,600

(22) Filed: Apr. 6, 2015

(30) Foreign Application Priority Data
Nov. 27, 2014 (TW) 103141148

(51) Int. Cl. H01L 45/00

(52) U.S. Cl. CPC H01L 45/1213; H01L 45/1253; H01L 45/1233; H01L 45/146

(57) ABSTRACT

The invention provides an inorganic light emitting memory, comprising resistive memory in tandem with inorganic light emitting element. It is ready to be extended into many other material systems for practical applications. In view of the unique features demonstrated by the integration of light emitters and memories, the inorganic light emitting memory may open up a new route for the development of integrated optoelectronic devices, optical communication, digital memories and recordable display panels and the likes.

### BACKGROUND OF THE INVENTION

1. Technical Field

The present invention relates to a memory and a method for producing the same, especially to an inorganic light-emitting memory and a method for producing the same.

2. Description of Related Art

Numerous progresses have been achieved in the last several decades on semiconductors, such as memories and light-emitting diodes. With substantial improvement in performance and reliability, these devices are now widely used in different applications. Further progress in the related field may involve research on devices with various data storage capabilities, more functions, and higher compatibility. It is worthy of note that, in the development of communication technology, more demand is placed on high-speed inter-chip and intra-chip links. The conventional electronic devices gradually approach their limit due to the increasing difficulties in controlling the carriers at shrinking sizes.

Among several candidates for next-generation memory cells, resistive random access memory (RRAM) based on a simple two-terminal electrical switch has the potential to serve as a replacement for conventional memory structures due to its good switching properties, low power consumption and especially, three-dimensional multilayer stacking to achieve high density memories. Nevertheless, such RRAMs are still read in a serial sequence in which data are transmitted by scanning one bit after another. To significantly accelerate data transfer in practical applications, memories designed for parallel data reading are called for.

Korean patent publication No. 2011-0051427 discloses an organic light-emitting memory device comprising an organic memory coated with and sandwiched between an upper electrode material and a lower electrode material in order for the organic light-emitting memory device to serve the dual functions of a light-emitting element and a memory element.

### BRIEF SUMMARY OF THE INVENTION

While organic light-emitting memory devices have been successfully developed, the properties of organic materials such poor thermo-stability and instability make those memory devices suitable for use only at room temperature or in vacuum and have limited further applications. For example, an organic light-emitting memory device cannot be integrated with the chip of a central processing unit simply because the high temperature generated by operation of the central processing unit is detrimental to the memory device.

To solve the above problem, the present invention aim to provide an inorganic light-emitting memory (ILEM), comprising: an inorganic light-emitting element and a resistive memory element stacked on the inorganic light-emitting element.

Preferably, the inorganic light-emitting element is a metal-insulator-metal (MIM), metal-insulator-semiconductor (MIS), p-n junction, or multiple-quantum-well (MQW) structure.

Preferably, the inorganic light-emitting element is further processed by lasing such that specific wavelength bands of light emitted by the inorganic light-emitting element laser.

Preferably, the resistive memory element is a metal-insulator-metal (MIM) structure. The metal-insulator-metal (MIM) structure of the resistive memory element includes an insulator layer formed of a binary or ternary oxide.

Preferably, the inorganic light-emitting element is a metal-insulator-metal (MIM) or metal-insulator-semiconductor (MIS) structure and the resistive memory element is a metal-insulator-metal (MIM) structure, the inorganic light-emitting element and the resistive memory element share a common metal layer where the resistive memory element is stacked on the inorganic light-emitting element. Preferably, the shared common metal layer is a graphene layer.

Preferably, the metal-insulator-metal (MIM) structure of the resistive memory element includes a metal particle layer formed between an upper metal layer and an insulator layer by coating. More preferably, the metal particle layer is formed of a metal having a +1 valence and high activity or metal having a +3 valence, such as Al.

Preferably, the metal-insulator-metal (MIM) structure of the resistive memory element includes metal layers selected from the group consisting of graphene, aluminum-doped zinc-oxide (AZO), indium tin oxide (ITO), indium zinc oxide (IZO) and transparent conducting oxide (TCO).

In contrast to the conventional electric memories, the inorganic light-emitting memory of the present invention allows data in the memory to be read optically. For instance, an optical transducer (e.g., a charge-coupled device, or CCD) can be used to receive data when the light-emitting memory is turned on. More specifically, a region which is not emitting light can be viewed as the logic “0”, and a light-emitting region, as the logic “1”. By monitoring the inorganic light-emitting memory, the optical transducer can detect and distinguish the various light emissions of the inorganic light-emitting memory so that data are readable as both optical signals and electrical signals in a parallel manner, thereby achieving high-speed data bandwidth. The present invention thus provides a novel inorganic light-emitting memory which works as an active device.

Furthermore, the manufacturing process of organic memories is totally different from that of inorganic memories. The inorganic light-emitting memory of the present invention overcomes the aforesaid drawbacks of its organic counterparts (i.e., poor thermo-stability and instability) and therefore has wider applicability and higher practical value.

### BRIEF DESCRIPTION OF THE SEVERAL VIEWS OF THE DRAWINGS

The structure and the advantages of the present invention will be best understood by referring to the following detailed description of some illustrative embodiments in conjunction with the accompanying drawings, in which:

FIG. 1(a) is a schematic structural diagram of example 1 of the present invention, and FIG. 1(b) shows the photoluminescence (PL) spectrum of p-GaN at room temperature;

FIG. 2(a) shows the I-V characteristic curves of the Ag/second SiO₂/graphene memory element in example 1, and FIG. 2(b) is a plot showing the switching characteristics of the Ag/second SiO₂/graphene memory element in example 1 over 100 switching cycles;

FIG. 3(a) shows the I-V characteristic curves of the inorganic light-emitting memory in example 1, and FIG. 3(b) is a plot showing the switching characteristics of the inorganic light-emitting memory in example 1 over 100 switching cycles;

FIG. 4(a) is a schematic structural diagram of example 2 of the present invention, and FIG. 4(b) is an electron microscope image of the Ag nanoparticle layer in the structure of example 2 of the present invention;

FIG. 5(a) shows the I-V characteristic curves of the AZO/Ag nanoparticles/SiO₂/graphene memory element in example 2, and FIG. 5(b) is a plot showing the switching characteristics of the AZO/Ag nanoparticles/SiO₂/graphene memory element in example 2 over 10 switching cycles; and

FIG. 6(a) shows the I-V characteristic curves of the inorganic light-emitting memory in example 2, and FIG. 6(b) is a plot showing the switching characteristics of the inorganic light-emitting memory in example 2 over 100 switching cycles.

### DETAILED DESCRIPTION OF THE INVENTION

Hereinafter, illustrative embodiments and examples of the present disclosure will be described in detail with reference to the accompanying drawings so that inventive concept may be readily implemented by those skilled in the art.

However, it is to be noted that the present disclosure is not limited to the illustrative embodiments but can be realized in various other ways. In the drawings, certain parts not directly relevant to the description are omitted to enhance the clarity of the drawings, and like reference numerals denote like parts throughout the whole document.

Throughout the whole document, the term “comprises or includes” and/or “comprising or including” used in the document means that one or more other components, steps, operations, and/or the existence or addition of elements are not excluded in addition to the described components, steps, operations and/or elements. The terms “about or approximately” or “substantially” are intended to have meanings close to numerical values or ranges specified with an allowable error and intended to prevent accurate or absolute numerical values disclosed for understanding of the present invention from being illegally or unfairly used by any unconscionable third party.

The present invention provides an inorganic light-emitting memory. Herein, the term “inorganic light-emitting memory” (ILEM) refers to a device formed by a resistive memory element stacked on an inorganic light-emitting element so as to provide the functions of a memory and of a light-emitting semiconductor and allow data to be transferred through both electrical signals and optical signals. The bistable light-emitting state and the resistance switching property may result from filamentary conduction paths, as detailed further below.

The inorganic light-emitting element of the inorganic light-emitting memory of the present invention can be any of those commonly used in the prior art without limitation, such as an inorganic light-emitting element having a metal-insulator-metal (MIM), metal-insulator-semiconductor (MIS), p-n junction, or multiple-quantum-well (MQW) structure.

MIM structures are well known in the art, one common but non-limiting example of which is the Al-Al₂O₃-Au structure, whose preparation process is briefly stated as follows. A strip of Al is evaporation-deposited on a sheet of glass by a vacuum coating method. Once the Al strip oxidizes in air, a natural oxidation layer about 3 nm thick is formed. To prevent edge breakdown, a layer of MgF₂ is evaporation-deposited on either side of the Al strip. Lastly, a strip of Au, about 40 nm thick and perpendicular to the Al strip, is formed by evaporation deposition to create an Al-Al₂O₃-Au tunnel structure. When a direct-current (DC) bias voltage of about 3-5 V is applied between Au (i.e., the positive electrode) and Al (i.e., the negative electrode), the surface of the structure emits visible light.

MIS structures are also well known in the art, and it is understood that the metal layer in such a structure is not literally limited to metal but may include any electrically conductive material. In a preferred embodiment of the present invention, this electrically conductive layer is made of graphene, and the resulting MIS structure is hence a graphene-insulator-semiconductor (GIS) structure.

While there are no limitations on the insulator layer in the aforesaid MIM and MIS structures, a binary or ternary oxide is preferably used. In a preferred embodiment of the present invention, the insulator layer is formed of silicon dioxide.

There are also no limitations on the inorganic semiconductor in the aforesaid MIS structures. For example, group III-V or group II-VI inorganic semiconductors are applicable. Preferably, a group III-nitride semiconductor is used, for this kind of semiconductors are already employed in photoelectric devices and are mature in terms of manufacturing techniques. An InGaN-based light-emitting diode (LED) or laser diode (LD), for instance, can emit light in the ultraviolet to visible regions of the spectrum. GaN is also suitable for use. Not only is it easier to form a high-quality GaN film than one made of the ternary InGaN, but also GaN is capable of strong light emission. Moreover, phosphor powder can be incorporated to generate blue light, or quantum dots can be added in an appropriate concentration to produce the desired light color. More preferably, p-type GaN (p-GaN) is used due to the fact that, when the insulator layer is formed of silicon dioxide, the barrier height of SiO₂/p-GaN is greater than that of SiO₂/n-GaN. Using p-GaN as the substrate is therefore advantageous in that an inversion layer will be formed near the SiO₂/p-GaN interface to facilitate accumulation of electrons. The accumulated electrons can readily tunnel through the holes in the overlying metal layer (e.g., a graphene layer) to generate light.

A p-n junction inorganic semiconductor refers to a semiconductor crystal whose one side is turned into a p-type semiconductor by doping and whose opposite side, an n-type semiconductor by doping differently. Such semiconductors are well known in the art. For instance, a silicon (or germanium) crystal can be doped with a small amount of phosphorus (or antimony) as the dopant to form an n-type semiconductor. More specifically, when an atom of the semiconductor (e.g., silicon) is replaced by a dopant atom (e.g., a phosphorus atom), four of the five outermost electrons of the phosphorus atom form covalent bonds with the neighboring semiconductor atoms. Meanwhile, the remaining electron is hardly bound and tends to become a free electron. Therefore, an n-type semiconductor is a semiconductor with a relatively high concentration of free electrons and owes its electrical conductivity mainly to electrical conduction by the free electrons. On the other hand, a silicon (or germanium) crystal can be doped with a small amount of boron (or indium) as the dopant to form a p-type semiconductor. More specifically, when an atom of the semiconductor (e.g., silicon) is replaced by a dopant atom (e.g., a boron atom), the three outermost electrons of the boron atom form covalent bonds with the neighboring semiconductor atoms, leaving behind an “electron hole” tending to attract a bound electron in order to be “filled”, and the electron hole, once filled, becomes a negatively charged ion. That is to say, a p-type semiconductor is electrically conductive because of a relatively high concentration of “electron holes”, which are “equivalent” to positive charges.

Multiple-quantum-well (MQW) structures for use as inorganic semiconductor light-emitting elements are well known in the art. Typically, the active layer of an inorganic light-emitting diode is a multiple-quantum-well structure. If the active layer contained only one quantum well, the space for receiving carriers would be limited, which in turn would lead to a carrier overflow and consequently an increased threshold current, and because of which the inorganic light-emitting diode would be susceptible to ambient temperature. This is why the number of quantum wells must be increased to form the so-called multiple quantum wells.

The inorganic light-emitting element can be further processed by lasing. In fact, any known lasing techniques can be adopted. For example, the interior of the inorganic light-emitting element can be plated with metal particles, or some protruding structures (e.g., nanoscale bar-like structures) or cyclic structures can be grown on the inner surface of the inorganic light-emitting element to enhance light emission efficiency. As certain portions (of specific wavelengths) of the light emitted by the inorganic light-emitting element resonate in the resonance chambers formed by such special surface structures, signals of specific wavelengths are amplified, and lasing is achieved if the full width at half maximum of the spectrum of these signals is less than 2 nm.

The resistive memory element of the inorganic light-emitting memory of the present invention can be any of those well known in the art, the most common structure of which is the metal-insulator-metal (MIM) structure. In the past, the metal layers are typically pure metal films formed of Au, Ag, Pt, Cu, Al, Cr, Pd, or Rh, with a thickness less than 10 nm. Nowadays, however, the metal layers are not literally limited to metal but may include any electrically conductive material. In a preferred embodiment of the present invention, the lower electrically conductive layer is formed of graphene, and the other metal layer is preferably a transparent conductive layer formed of a transparent conducting oxide (TCO) such as aluminum-doped zinc-oxide (AZO), indium tin oxide (ITO), or indium zinc oxide (IZO) in order not to block the light emitted by the underlying light-emitting element.

To increase the formation of metal filament networks of the transparent conductive layer, a metal particle layer can be formed between the upper metal layer and the insulator layer by coating, wherein the metal particles are of a metal having a +1 valence and high activity, such as Ag, Cu, Ni, etc, or metal having a +3 valence, such as Al.

If the inorganic light-emitting element is a metal-insulator-metal (MIM) or metal-insulator-semiconductor (MIS) structure and the resistive memory element is a metal-insulator-metal (MIM) structure, the inorganic light-emitting element and the resistive memory element share a common metal layer where the resistive memory element is stacked on the inorganic light-emitting element, with a view to integrating the two elements and downsizing the resulting assembly.

### EXAMPLES

The disclosure of the present invention is further illustrated below by way of embodiments and the accompanying drawings. The disclosed invention, however, is by no means limited to those embodiments and drawings.

### Example 1

### Inorganic Light-Emitting Memory with Ag/SiO₂/Graphene/SiO₂/pGaN Structure

Graphene is formed on a copper foil by chemical vapor deposition (CVD) at a temperature as high as 1000° C., with the source of carbon being a mixture of methane and hydrogen. More specifically, carbon atoms from the gaseous reactant deposit on the metal substrate at about 1000° C. through chemical absorption. Then, the graphene is coated with poly(methyl methacrylate), or PMMA, in order to be aligned with and transferred to a p-GaN.

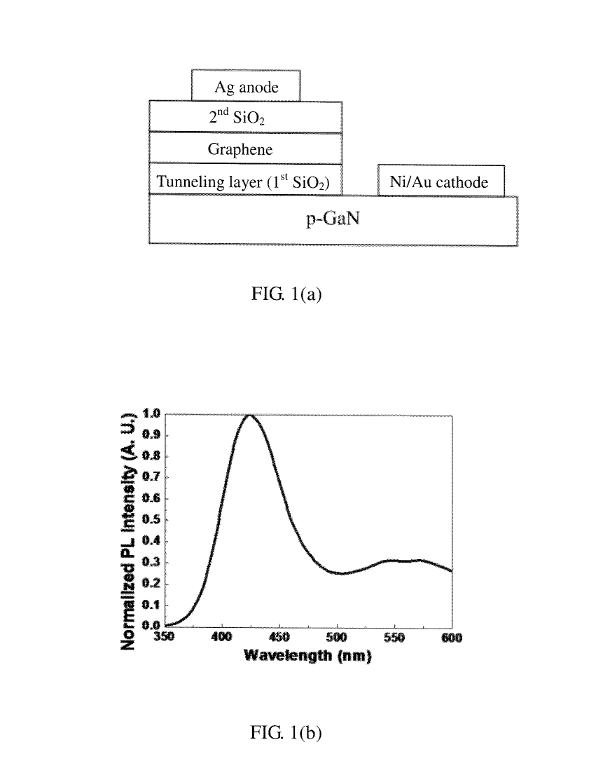

In this embodiment, the device structure consists of Ag/2^{nd} SiO₂/graphene/1^{st} SiO₂/p-GaN. The p-GaN was doped by Mg with the hole concentration in the range of 6×10¹⁶ cm⁻³. Initially, p-GaN wafer was rinsed in acetone, isopropanol and DI water. Ni/Au was firstly deposited on p-GaN with annealing to obtain an ohmic contact. The first SiO₂ layer with a thickness of 3 nm was grown on p-GaN via RF sputtering after the formation of Ni/Au ohmic contact. The graphene layer was then assembled by a transfer process on p-GaN. The second SiO₂ layer with a thickness of 50 nm was sequentially deposited on top of graphene. The ILEM was completed by the deposition of Ag electrode to serve as anode (the resistive memory element MIM and the inorganic light-emitting element GIS share a common graphene layer) shown in FIG. 1(a). The graphene was used as current spreading electrode, the Ni/Au contact was used as current collecting electrode (cathode) and the Ag contact was used as control electrode (anode).

In addition, to serve as the transparent conducting layer, graphene also works as a stable interlayer without affecting the redox reaction in the formation of metal filament networks. Moreover, because the tunneling 1^{st} SiO₂ layer only has a thickness of about 3 nm, the transferred graphene on top of the 1^{st} SiO₂ layer does not need the addition process for coating a metal film. It can avoid the damage of the thin 1^{st} SiO₂ layer and prevent leakage current.

In our device geometry, the top Ag electrode works as a reflective layer and the emitted light was detected from the p-GaN side. FIG. 1(b) shows the photoluminescence (PL) spectrum of p-GaN under light excitation of 325 nm at room temperature. The PL spectrum is dominated by a blue emission peak at ˜415 nm and a broadband yellow emission at ˜550 nm.

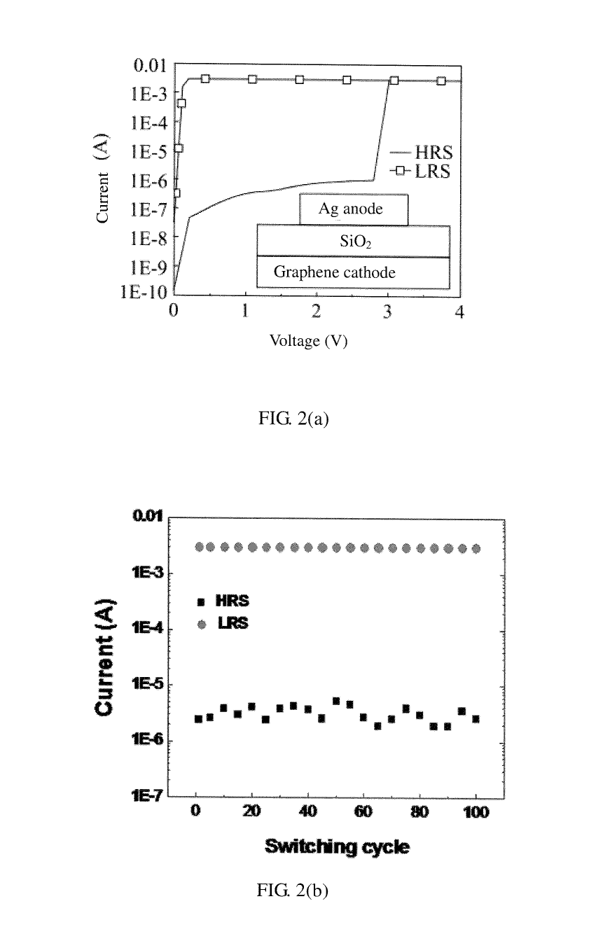

Bistable switching performance of the memory cell is important to control the luminescence arising from of the ILEM. Therefore, we investigated the performance of the memory cell first. FIG. 2(a) shows the I-V characteristics of the Ag/2^{nd} SiO₂/graphene memory cell at room temperature; as can be seen, the Ag/2^{nd} SiO2/graphene memory cell was at the HRS initially and showed a low-current characteristics in the low voltage range; when the applied voltage exceeded to a certain value (˜3 V), the injection current increased dramatically followed by an abrupt increase in the current flow and was switched from the HRS to the LRS, where the ON/OFF current ratio is about 10³. To prevent damage during the I-V measurements, the present invention set a compliance current at 3 mA. The state transition is equivalent to the “writing” command in the digital storage devices and the ON/OFF current ratio promises a misreading probability in data access. According to previous reports, the conducting filament model with an electrochemical reaction is responsible for the resistive switching behavior. Hence, the state of Ag/2^{nd} SiO₂/graphene memory cells can be switched between the HRS and the LRS using dc voltages.

Switching performances between HRS and LRS were evaluated by performing the operation 100 times, as shown in FIG. 2(b). The current fluctuation at the high resistance state (HRS) may come from the incomplete dissolution of metal filament network. It is clear that there was a little fluctuation of the HRS and LRS current levels and the ON/OFF ratio was quite stable.

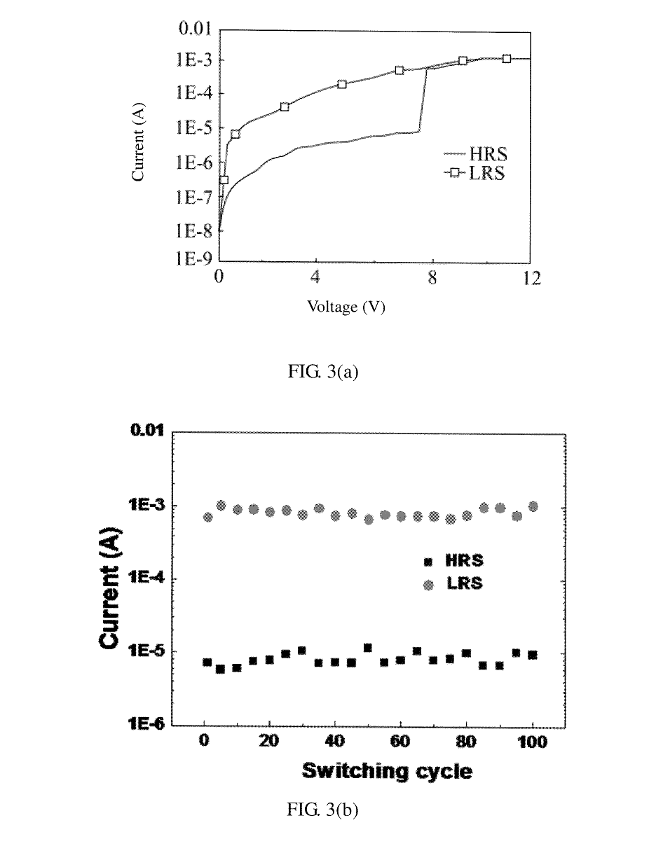

FIG. 3(a) shows the I-V characteristic of the ILEM at room temperature, which is similar to the I-V characteristics shown in FIG. 2(a). The current flow sharply increased by 2 orders of magnitude at a critical voltage (˜8 V) and reflected the fact that the ILEM was switched from the HRS to the LRS. The bistable switching performance of ILEM is due to the bistability of Ag/2^{nd} SiO₂/graphene memory cell. Noting that the ILEM was achieved by developing a tandem structure, in which the writing voltage was expended since the voltage was applied to the graphene/SiO₂/p-GaN (GIS-LED) and the Ag/2^{nd} SiO₂/graphene (memory cell). Because the I-V characteristics depend on the corresponding HRS or LRS, it is expected that the electroluminescence (EL) intensity of ILEM should be different when the memory cell was switched from HRS to LRS. When the ILEM is at the HRS, there is no EL signal until ˜8 V bias. However, when the ILEM is at the LRS, the EL signal is detectable when the bias exceeds ˜6 V. The emission state of ILEM can be switched between the HRS and the LRS based on the I-V characteristics of the Ag/2^{nd} SiO₂/graphene memory cell. Switching performances between the HRS and LRS were evaluated by performing the operation 100 times, as shown in FIG. 3(b). It is clear that the switching characteristic of EL signal is also quite stable.

### Example 2

### Inorganic Light-Emitting Memory Having the “AZO/Ag Nanoparticles/SiO₂/Graphene/MQW LED” Structure

Graphene is formed on a copper foil by chemical vapor deposition (CVD) at a temperature as high as 1000° C., with the source of carbon being a mixture of methane and hydrogen. More specifically, carbon atoms from the gaseous reactant deposit on the metal substrate at about 1000° C. through chemical absorption. Then, the graphene is coated with poly(methyl methacrylate), or PMMA, in order to be aligned with and transferred to an MQW light-emitting diode.

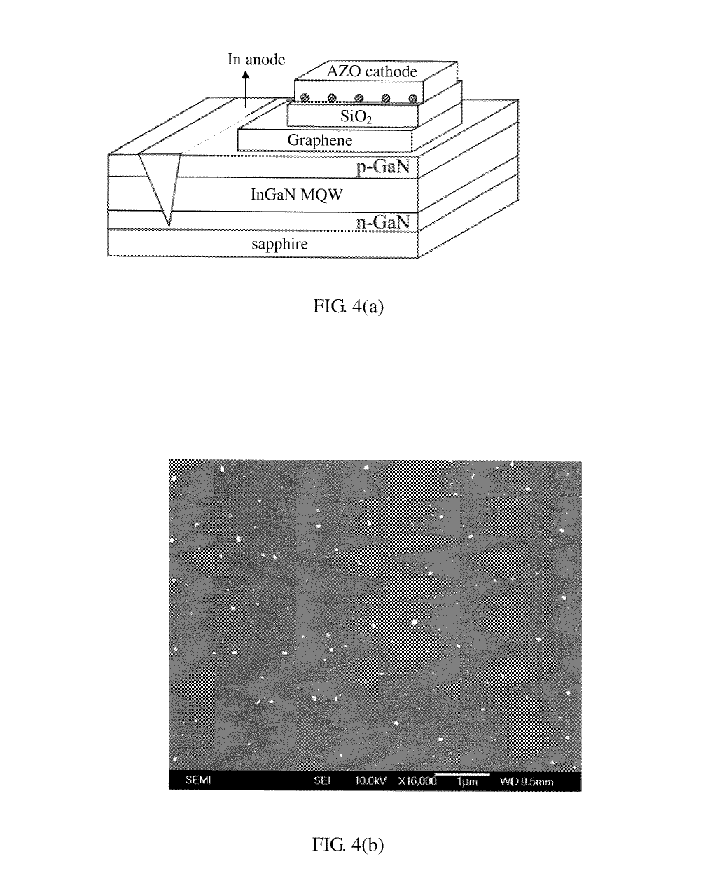

As shown in the structural diagram of FIG. 4(a), the structure of this embodiment includes AZO, Ag nanoparticles, SiO₂, graphene, and an MQW light-emitting diode. The MQW light-emitting diode is formed by sequentially depositing a layer of n-GaN, a multiple-quantum-well (MQW) layer of GaN/InGaN, and a layer of p-GaN on a sapphire substrate. Once formed, the MQW light-emitting diode is rinsed with acetone, ethanol, and deionized water. Then, a groove is formed in the MQW light-emitting diode by cutting, and the groove is plated with indium, which serves as the cathode. After that, the graphene layer is transferred to the MQW light-emitting diode and is provided with a 30-nm-thick SiO₂ layer by radio-frequency (RF) sputtering. Then, a layer of Ag nanoparticles (schematically shown in FIG. 4a as the circular dots above the SiO₂ layer) is formed by RF sputtering, followed by the AZO anode, formed also by RF sputtering. Thus, the inorganic light-emitting memory is completed, with the MIM resistive memory element integrated, and sharing the same graphene layer, with the MQW LED inorganic semiconductor light-emitting element. The graphene layer functions as a current spreading electrode; the indium, as a current collecting electrode (cathode); and the AZO, as a control electrode (anode).

In addition, the AZO forms a transparent conductive layer while the Ag nanoparticles form a metal particle layer which has no adverse effect on light permeability. The silver atoms also provide oxidation and reduction in the resulting metal filament network. The size and distribution of the Ag nanoparticles are shown in FIG. 4(b).

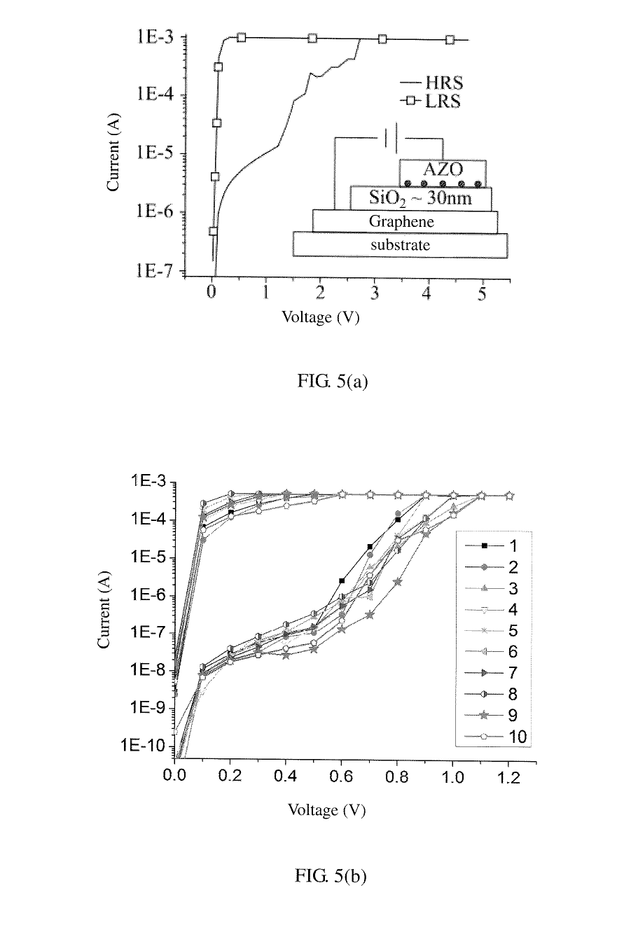

As the bistable switching performance of the memory element is crucial in controlling the luminescence of the inorganic light-emitting memory, the performance of the memory element was tested. FIG. 5(a) shows the I-V characteristic curves of the AZO/Ag nanoparticles/SiO₂/graphene structure at room temperature. As can be seen in the drawing, the AZO/Ag nanoparticles/SiO₂/graphene memory element was initially in a high-resistance state (HRS) and featured low current in a low-voltage range. When the voltage applied exceeded a certain range (1-2V), the injection current rose abruptly, and the structure was switched from HRS to a low-resistance state (LRS), where the ON/OFF current ratio is about 10². To prevent damage during I-V measurement, a limiting current of 1 mA was set. The switching of the states is equivalent to the “writing” command in a digital storage device. As the filamentary conduction paths, where electrochemical reactions take place, are known to be responsible for the resistance switching behavior, a DC voltage can be used to switch between HRS and LRS of the AZO/Ag nanoparticles/SiO₂/graphene structure.

The performance of switching between HRS and LRS was assessed by performing the aforesaid operation 10 times. As shown in FIG. 5(b), the current levels and the ON/OFF ratio remained quite stable in both HRS and LRS.

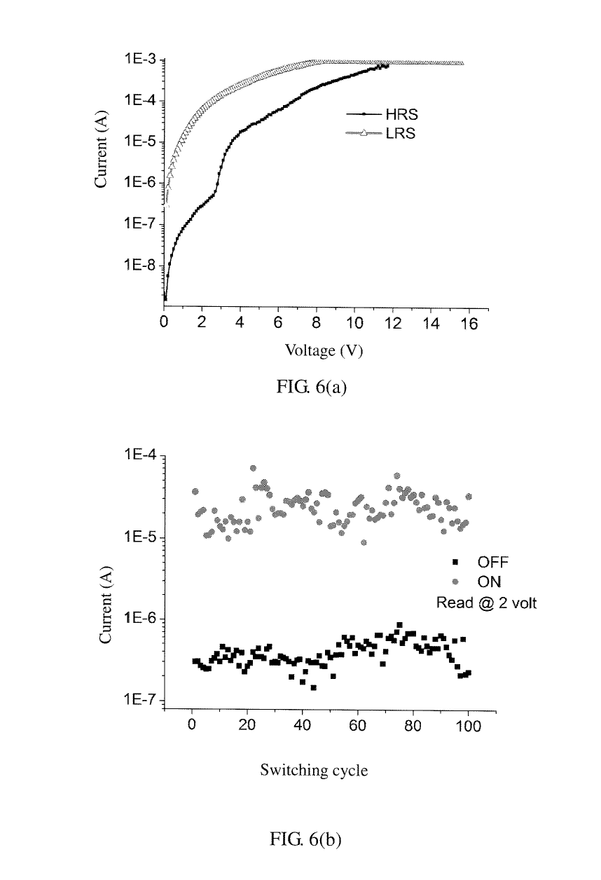

The I-V characteristic curves of the inorganic light-emitting memory at room temperature are plotted in FIG. 6(a) and are similar to the I-V characteristic curves in FIG. 5(a). As shown in FIG. 6(a), current rose precipitously by two orders of magnitude at a critical voltage (˜3V), which reflects the inorganic light-emitting memory being switched from HRS to LRS. The bistable switching performance of the inorganic light-emitting memory originates from the bistability of the AZO/Ag nanoparticles/SiO₂/graphene memory element. With the inorganic light-emitting memory being a series-connected structure, a writing voltage will increase after it is applied to the graphene/MQW LED element and the AZO/Ag nanoparticles/SiO₂/graphene memory element. Since the I-V characteristics depend on the corresponding HRS or LRS, it is expected that the electroluminescence (EL) intensity of the inorganic light-emitting memory should be different from that of the memory element when switched from HRS to LRS. Test results show that while the inorganic light-emitting memory was in HRS, EL signals did not occur until the bias voltage reached about 4 V. When the inorganic light-emitting memory was in LRS, however, EL signals were detected as soon as the bias voltage exceeded about 2 V. As shown in the insert of FIG. 6(a), the light-emitting state of the inorganic light-emitting memory can be switched between HRS and LRS based on the I-V characteristics of the AZO/Ag nanoparticles/SiO₂/graphene memory element. According to FIG. 6(b), which shows the HRS-LRS switching performance evaluation result obtained by effecting 100 switching cycles, the switching characteristics of EL signals were fairly stable.

While example embodiments have been disclosed herein, it should be understood that other variations may be possible. Such variations are not to be regarded as a departure from the spirit and scope of example embodiments of the present application, and all such modifications as would be obvious to one skilled in the art are intended to be included within the scope of the following claims.

What is claimed is:

1. An inorganic light emitting memory, comprising: an inorganic light emitting element and a resistive memory element stacked on the inorganic light emitting element.

2. The inorganic light emitting memory of claim 1, wherein the inorganic light-emitting element is a metal-insulator-metal (MIM), metal-insulator-semiconductor (MIS), p-n junction, or multiple-quantum-well (MQW) structure.

3. The inorganic light-emitting memory of claim 1, wherein the inorganic light-emitting element is further processed by lasing such that specific wavelength bands of light emitted by the inorganic light-emitting element laser.

4. The inorganic light-emitting memory of any of claim 1, wherein the resistive memory element is a metal-insulator-metal (MIM) structure.

5. The inorganic light-emitting memory of claim 4, wherein when the inorganic light-emitting element is a metal-insulator-metal (MIM) or metal-insulator-semiconductor (MIS) structure and the resistive memory element is a metal-insulator-metal (MIM) structure, the inorganic light-emitting element and the resistive memory element share a common metal layer where the resistive memory element is stacked on the inorganic light-emitting element.

6. The inorganic light-emitting memory of claim 5, wherein the shared common metal layer is a graphene layer.

7. The inorganic light-emitting memory of claim 4, wherein the metal-insulator-metal (MIM) structure of the resistive memory element includes a metal particle layer formed between an upper metal layer and an insulator layer.

8. The inorganic light-emitting memory of claim 7, wherein the metal particle layer is formed of a metal having a +1 valence and high activity.

9. The inorganic light-emitting memory of claim 4, wherein the metal-insulator-metal (MIM) structure of the resistive memory element includes an insulator layer formed of a binary or ternary oxide.

10. The inorganic light-emitting memory of claim 4, wherein the metal-insulator-metal (MIM) structure of the resistive memory element includes metal layers formed of graphene or a transparent conducting oxide (TCO) selected from the group consisting of aluminum-doped zinc-oxide (AZO), indium tin oxide (ITO), and indium zinc oxide (IZO).
